(19) United States
(12) Patent Application Publication
(10) Pub. No.: US 2010/0183957 A1
(43) Pub. Date: Jul. 22, 2010

(54) Method of Patterned Media Template Formation and Templates

(75) Inventors: Zhongyan Wang, Maple Grove, MN (US); Thomas R. Boonstra, Chaska, MN (US); Mark H. Ostrowski, Lakeville, MN (US); Alexandre V. Demtchouk, Eden Prairie, MN (US); Xilin Peng, Bloomington, MN (US); Kaizhong Gao, Eden Prairie, MN (US)

Correspondence Address: SEAGATE TECHNOLOGY LLC;C/O NOVAK DRUCE & QUIGG LLP, 1000 LOUISIANA, Fifty-Third Floor, HOUSTON, TX, 77002, US

(73) Assignee: Seagate Technology LLC, Scotts Valley, CA (US)

(21) Appl. No.: 12/357,296

(22) Filed: Jan. 21, 2009

(51) Int. Cl. G03F 1/14

(52) U.S. Cl. 430/5; 216/11

(57) ABSTRACT

Aspects include methods to produce pattern media templates and the templates. A pattern of resist structures is formed on a first material layer. A conformal layer of a second material is deposited on the resist pattern, covering tops and side walls of the resist structures. The first material is more resistant to ion milling than the second material, and less resistant to plasma etching than the second material. The first material can be amorphous carbon and the second material can be aluminum oxide. The second material is removed on the tops, and preserved on the side walls. The resist structures and portions of the first layer not supporting second layer material are removed by plasma. The remaining structure is 2× denser than the resist pattern. Conformal deposition of second material and ion milling can be repeated. CMP removes the second material down to a portion of remaining first material, and remaining first material is removed by plasma, leaving a 4× denser pitch pattern structure formed from the second material.

### BACKGROUND

1. Field

The following relates to patterned data storage media and more particularly to templates for creating patterns on media and methods for producing such templates.

2. Related Arts

Media for magnetic data storage comprises a substrate on which a recording layer is formed, and data is stored on the media by changing magnetic polarities among consecutive magnetic domains on the recording layer. The domains of most current magnetic storage media comprise multiple distinct grains of a magnetic material. Making the domains smaller allows denser media. However, there is a limit as to how much the domains can be shrunk and still be comprised of a plurality of distinct grains.

One particular effect that prevents shrinkage of domain size is the super-paramagnetic effect. The super-paramagnetic effect occurs when the grain volume is too small to prevent thermal fluctuations from spontaneously reversing magnetization direction in the grains.

One approach to delaying the onset of the super-paramagnetic effect is to use bit patterned media, where each bit is a single magnetic switching volume (e.g., a single grain or a few strongly coupled grains), as disclosed in R. D. Terris et al., J. Phys. D: Applied Physics 38, R199 (2005). In order to keep thermally activated reversal at an acceptable level, KᵤV/k_{b}T where Kᵤ is the magnetic anisotropy, V the magnetic switching volume, k_{b} the Boltzmann constant, and T the temperature in Kelvin. Their ratio must remain greater than approximately 60 for conventional longitudinal media per D. Weller, et al. “Thermal Effect Limits in Ultrahigh-Density Magnetic Recording”, IEEE Trans. on Magnetics 35, 4923 (1999). To maintain a sufficient SNR, it is desirable to conserve the number of grains per bit as the density is increased. The switching volume in discrete dots is equal to the bit size, and dots smaller than 10 nm can be thermally stable.

As would be evident, bit patterned media requires a method for producing a regular pattern of extremely small recording domains that are separated from one another. A variety of approaches have been considered to accomplish such pattern formation. One technique includes usage of templates to stamp patterns into resist, for example, which can be cured and used as a mask in a variety of further processing to create the pattern. For example, thicker resist regions can shield underlying regions from etching processes or the like, which can be used to create non-magnetically active regions separating the shielded regions, which will serve as the recording domains (also called “dots” in this description, as is conventional in the industry).

Thus, techniques to create the templates used in such stamping are also necessary. Increasing bit density is a continued goal, and requires continued shrinkage of the size of each recording domain and the pitch between recording domains. For example, to reach a bit density of 1 trillion bits per square inch, a template needs to have a pitch on the order of 25 nm, and it is generally the case that the recording domain is on the order of one half the pitch, resulting in a recording domain on the order of 12-13 nm (some variation in these numbers would be expected based on lattice structures, and are given as motivational examples of the small dimensions involved). Good uniformity and tight tolerances also are important considerations.

Using such imprinting techniques for media creation is attractive, by comparison with using direct write techniques, such as E-beam lithography because of potential for higher throughput and lower costs. Also, it is expected that standard E-beam lithography will be challenged to scale to desired dot sizes, such as those under 25 nm, while also maintaining good throughput, uniformity and tolerances.

### BRIEF DESCRIPTION OF THE DRAWINGS

FIG. 1 depicts an example disc drive for data storage which may contain media according to these disclosures;

FIG. 2 depicts a top surface of a master template according to an example with resist deposited in concentric tracks on a surface supported by a substrate and an identified cross-section;

FIGS. 3-10 each depict the cross-section identified in FIG. 2 through various processing steps;

FIGS. 11-15 depict another example of cross-sections modified by various process steps, with a selected resist pattern and dimensioning information;

FIG. 16 depicts a flow chart for the steps used in producing the cross-sections depicted in FIGS. 3-10;

FIG. 17 depicts a top view of the master template after processing up to FIG. 6, illustrating an approximate doubling in track pitch compared with the pitch of the original deposited resist pattern of FIG. 2;

FIG. 18 depicts a top view of the master template after processing through FIG. 10, illustrating an approximate quadrupling in track pitch compared with the pitch of the original deposited resist pattern of FIG. 2;

FIG. 19 illustrates steps of a method for using the template formed in the above examples to provide production templates that can be used to produce articles of recording media; and

FIG. 20 illustrates relative removal rates for difference substances in a chemical mechanical polishing step that can be employed in methods to produce templates according to these examples.

### SUMMARY

One exemplary aspect includes a method for the formation of bit patterned media templates.

In a first specific aspect, a method to achieve increased track density on a template for patterned media production (e.g., for Discrete Track Recording (DTR)), which also provides critical dimension control and uniformity is provided. This method is expected to allow critical dimensions on the order of 10 nm and at least four times pitch improvement over what could be achieved by a direct patterning step.

The method comprises imposing a first pattern of distinct concentric tracks composed of photo-resist (“resist”) material onto a 2-D surface formed of generally amorphous carbon, which in turn is disposed on a substrate. In some examples, the tracks can be separated by areas generally devoid of resist, such that the pattern exposes areas of the amorphous carbon between the columns. This step can include patterning with E-Beam lithography, UV lithography (e.g., at the 193 nm node, and so on).

A layer of Aluminum Oxide (Al₂O₃) is deposited, such that it covers the resist and any exposed carbon; the tops of the tracks and their sides are covered with a functionally uniform layer. Atomic Layer Deposition (ALD) can be used for such deposition. Then, a top layer of the Al₂O₃ and the Al₂O₃ from areas between the tracks is removed while preserving the Al₂O₃ on the sides of the columns, which can be accomplished by vertical Ar plasma milling. The resist and the amorphous carbon between the tracks are removed, leaving exposed resist between columns of Al₂O₃.

The exposed resist and amorphous carbon between the columns of Al₂O₃: are removed, such as with O₂ plasma. At this point, the template comprises a pattern of concentric rings at approximately twice the pitch of the pitch of the original resist pattern.

The method may continue with a further generally conformal Al₂O₃ deposition over the 2× pitch template. The resulting surface is milled (e.g., Ar ion milled) to remove the Al₂O₃ deposition in the trenches (i.e., between high points), which also removes some Al₂O₃ from the tops of the high points. The resulting template is planarized (such as with CMP), to expose the remaining carbon. The remaining carbon is removed from between walls of Al₂O₃ (such as with O₂ plasma), leaving a template with concentric tracks formed of Al₂O₃ at above four times a track pitch as the originally patterned resist.

Since the originally formed resist pattern can be formed using any of a variety of known methods and technologies, such as e-beam lithography, and so on, the track density can be improved upon by methods according to these examples. Thus, greater track density can be achieved, or optionally a faster and/or less expensive resist patterning methodology can be employed to reach a desired track pitch. Various extensions of these examples can be provided, and the shape of concentric tracks for DTR is an example application. Other shapes may be provided for other applications. The resist pattern can be defined, and the thicknesses of the layers can be selected to produce uniform ring patterns, separated with uniform spacing, for example. Other aspects include products, such as templates and articles of media formed according to methods presented in these disclosures.

### DETAILED DESCRIPTION

The following description is presented to enable a person of ordinary skill in the art to make and use various aspects of the invention. Descriptions of specific techniques, implementations and applications are provided only as examples. Various modifications to the examples described herein may be apparent to those skilled in the art from these disclosures, and the general principles defined herein may be applied to other examples and applications by those of ordinary skill without departing from the scope of the invention.

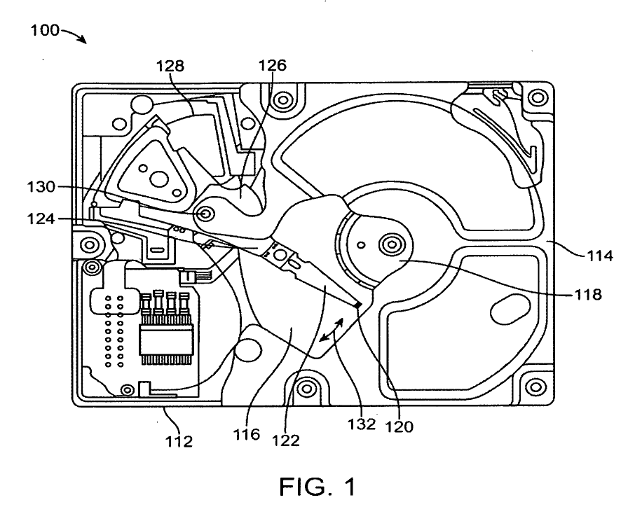

As explained below one exemplary aspect includes a method for the formation of bit patterned media that can be used in a storage device, such as a disc drive 100, illustrated in FIG. 1.

FIG. 1 depicts an example of disc drive 100 that can include media according to the following disclosures. Referring to FIG. 1, the Disc drive 100 includes a base 112 and a top cover plate 114. The base 112 is combined with cover plate 114 to form a sealed environment to protect the internal components from contamination by elements outside the sealed environment. The base and cover plate arrangement shown in FIG. 1 is well known in the industry; however, other arrangements of the housing components have frequently been used, and disc drive 100 implies no limitation in configuration of the Disc drive housing. Disc drive 100 further includes a Disc pack 116 that is mounted on a hub for rotation on a spindle motor (not shown) by a Disc clamp 118. Disc pack 116 includes one or more of individual Discs that are mounted for co-rotation about a central axis.

Each Disc surface has an associated read/write head 120 that is mounted to the Disc drive 100 for reading/writing to/from the Disc surface. In the example shown in FIG. 1, read/write heads 120 are supported by flexures 122 that are in turn attached to head mounting arms 124 of an actuator 126. The actuator shown in FIG. 1 is of the type known as a rotary moving coil actuator and includes a voice coil motor, shown generally at 128. Voice coil motor 128 rotates actuator 126 with its attached read/write heads 120 about a pivot shaft 130 to position read/write heads 120 over a desired data track along a path 132. FIG. 1 is shown as a general example of a usage for the articles of media that can be produced according to the disclosed methods, and FIG. 1 implies no limitation as to the structure, components, form factor, read/write head technology or the like that may be used in devices with such media articles.

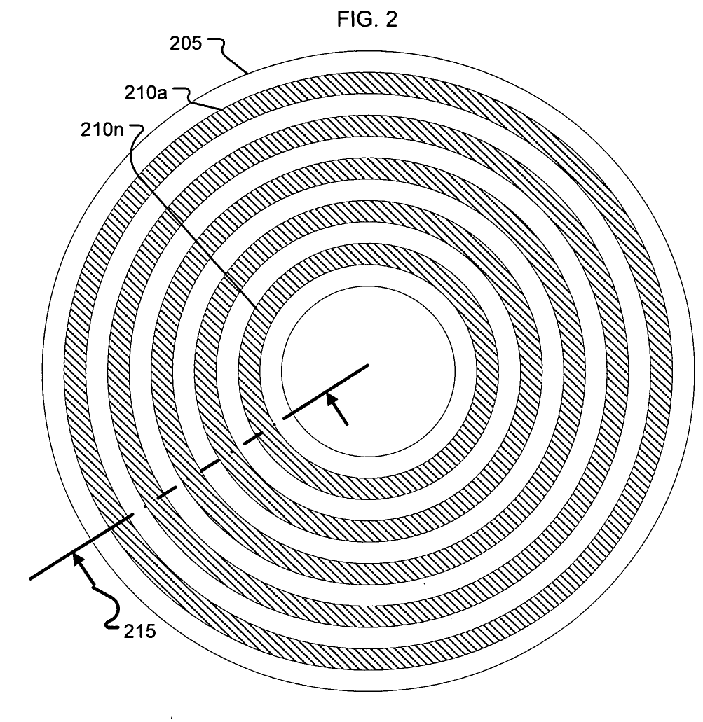

FIG. 2 illustrates a top view of a template substrate 205 supporting a resist pattern comprising a plurality of concentric rings, of which several are specifically identified, outer ring 210a and inner most ring 210n. Cross section 215 is identified and will be referenced below. The resist pattern can be formed by any number of example methods and technologies. For example, direct writing with an e-beam pattern can be used. The substrate 205 can comprise a number of layers, and in a first example, a surface on which the resist pattern is disposed predominantly comprises amorphous carbon.

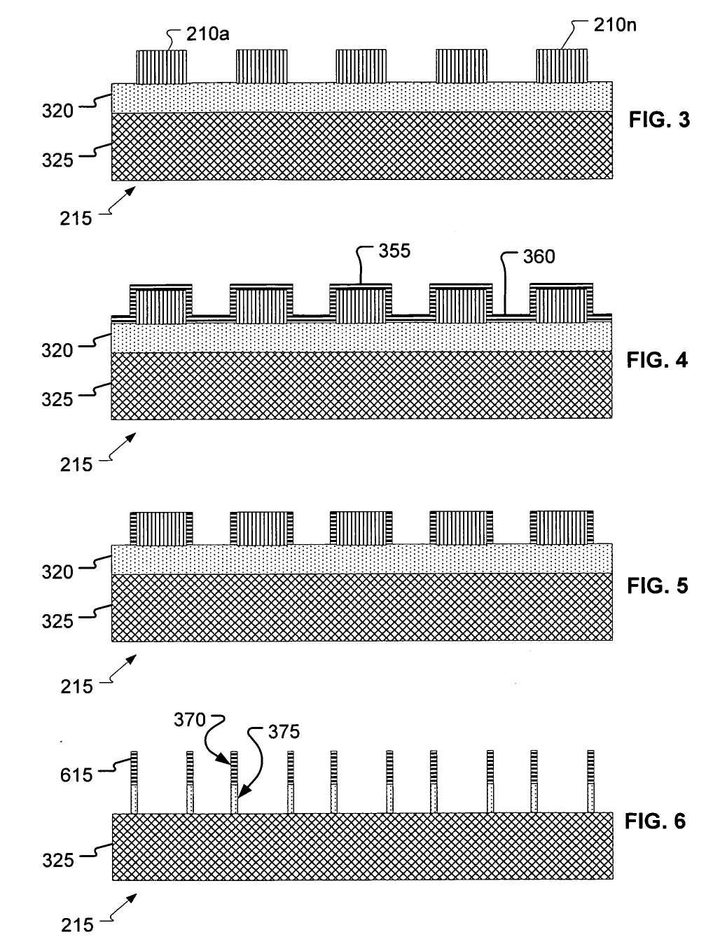

FIG. 3 illustrates a first example cross section of substrate 205 that comprises the resist pattern (rings 210a and 210n are identified). A carbon layer 320 supports the resist pattern and a structural layer 325 supports the carbon layer.

FIG. 4 illustrates a deposition of a generally conformal (e.g., equal thickness) layer 355 of Al₂O₃ over both the resist pattern and the exposed portions of carbon layer 320 (one formerly exposed portion identified as 360). This deposition can be provided using Atomic Layer Deposition (ALD) techniques known in the art.

FIG. 5 illustrates removal of the Al₂O₃ on tops of the resist, exposing the resist, as well as the layer of Al₂O₃ deposited over carbon layer 320. This removal of Al₂O₃ is to be directionally selective, in that the layer of Al₂O₃ on the side walls of the resist substantially are preserved. This directionally selective removal can be accomplished by ion milling, such as with Ar⁺ ions. Further selectivity can be provided by cooling the substrate, reducing the thermal energy of the ions, such that most of the ions do not have enough energy to break Al₂O₃ without assistance from the kinetic energy provided by the ion gun (and which is disposed to emit the ions in a substantially vertical direction).

FIG. 6 illustrates that from FIG. 5, the resist and most of carbon layer 320 are removed. This removal can be accomplished with a plasma etch, such as with an Oxygen plasma etch. The remaining carbon from the original carbon layer supports the walls of Al₂O₃ as shown in FIG. 5. One such structure is identified by carbon portion 375 and by Al₂O₃ portion 370. A further Al₂O₃ portion is identified for later reference. As can be illustrated, the etch depicted in FIG. 6 also is directional, in that the Al₂O₃ walls of the tracks (rings) should be maintained to the extent possible.

The product shown in FIG. 6 can be used as a template with approximately twice the track pitch of the originally disposed resist pattern. Thus, if a high density direct write e-beam process were conducted, the track density illustrated will be greater than such density. The product illustrated in FIG. 6 can be used as a master template for making other templates that will be used directly in methods to product articles of media (i.e., it can be gold template, used to make other templates). The pattern which is formed will be selected based on the pattern ultimately desired to be formed on the media article, and such pattern can be selected based on known considerations. Reference number 615 identifies an outer most structure formed the first material supporting the second material.

FIG. 7 illustrates that further processing of the product of FIG. 6 also can be provided, starting with a further deposition of a conformal layer 715 of Al₂O₃. The original Al₂O₃ wall 370 and the supporting carbon 375 is identified again. A further ion milling step removes the deposited Al₂O₃ from the spaces (also can be called trenches), one of which is identified as 720 in FIG. 8. This step also incidentally removes some amount of Al₂O₃ from the tops of the walls. This milling step also preferably is selective in that a rate of removal from horizontal surfaces should be greater than a rate of removal for vertical surfaces.

A Chemical Mechanical Planarization (CMP) is employed to planarize the product of FIG. 8, resulting in a structure generally in accordance with FIG. 9. CMP is a process that uses an abrasive, corrosive slurry to physically grind flat and chemically remove the microscopic topographic features on a wafer so that subsequent processes can begin from a flat surface. In this situation, the amorphous carbon shown disposed between each pair of features formed of Al₂O₃ from the second deposition serves as a stopping point, as it is comparatively more resistance to CMP than Al₂O₃. Other ways are known in the art also to stop CMP when a desired amount of material has been removed.

FIG. 9 illustrates that after CMP, a remaining portion of carbon has been exposed (example identified by reference 730) between the Al₂O₃ of the second deposition. Reference number 725 generally indicates the formed planarized surface defined by the CMP step. A portion of side wall 375 is shown as remaining.

The remaining portion of carbon is removed such as with oxygen plasma etch. FIG. 10 illustrates a final result of the process, in which a pitch of formations on the substrate have been approximately quadrupled from an original resist pattern pitch. A gap formed by removal of carbon 730 is identified as 750. An outermost and inner most shape are identified respectively as 760 and 761.

In the above example, ion milling was performed before CMP, which is preferred, but in other examples, CMP could be performed first, followed by ion milling. Such reversal of steps may be less preferable because of potential irregularities caused by the ion milling. An additional step of CMP could be provided. Such explanation illustrates that ordering of steps of example methods is not exclusive of other potential orderings or of additional steps.

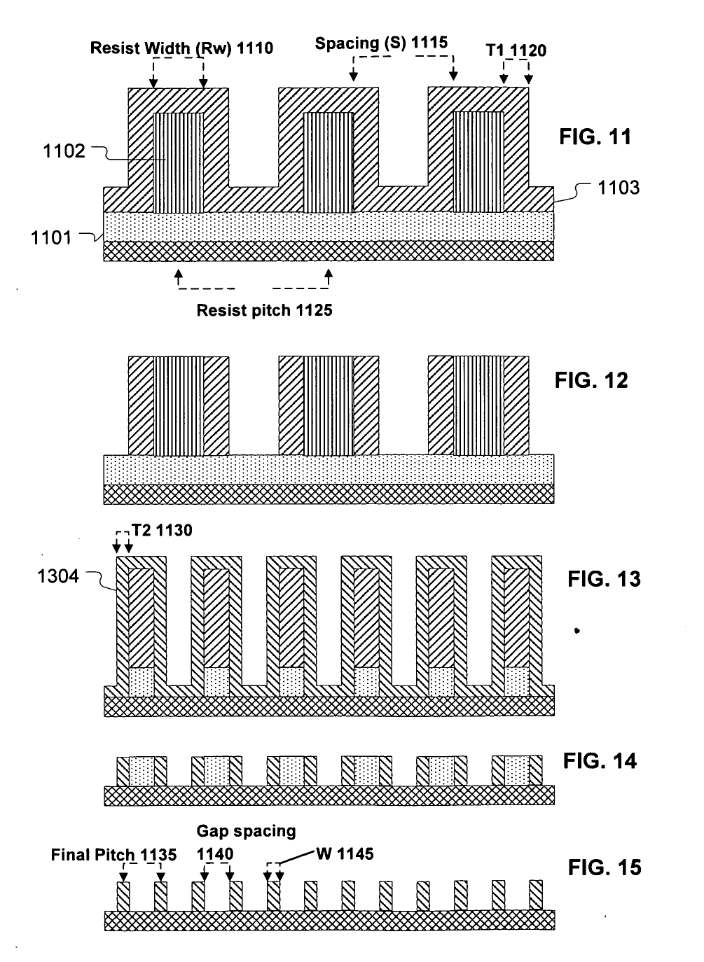

FIG. 16 illustrates a flow chart for a method 1600 according to the cross-section build illustrated in FIGS. 3-10. Method 1600 includes a step of depositing 1605 a resist pattern (such as concentric rings) on a surface of a first material, such as amorphous carbon. A first deposition of a second material (step 1610), such as Aluminum Oxide, is made over the resist and any exposed portions of the first material. Preferably the first deposition causes deposition of a generally even thickness layer (conformal layer). The second material coats sides and tops of the resist.

Step 1615 includes ion milling to remove horizontally disposed Aluminum Oxide at a rate faster than removal of Aluminum Oxide from vertically disposed surfaces (e.g., side walls of the resist). Thus, although the Aluminum Oxide was deposited conformally, the horizontal surfaces are exposed while retaining vertical Aluminum Oxide. Step 1620 includes etching the first material and resist, such as with an oxygen plasma. This etch also is performed directionally, such that horizontally exposed carbon and resist are etched at a rate greater than vertically exposed carbon. Also, the first and second material are to be selected so that the second material is more susceptible to ion milling than the second material and less susceptible to plasma etching than the first material. In other words, the first material should etch faster than the second material, while resist ion milling more than the second material. Amorphous carbon is an example of a first material according to these parameters, and Aluminum Oxide is an example of a second material according to these parameters.

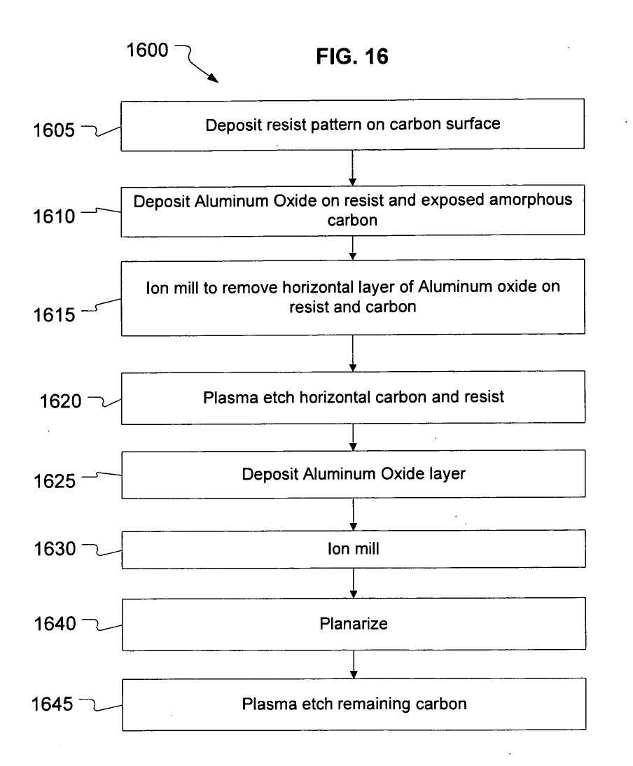

Subsequent to step 1620, a first template pattern results shown in cross-section in FIG. 6. A top surface therefore is shown in FIG. 17, where the resist pattern was a set of concentric rings, resulting also in a final pattern of concentric rings. Reference number 615 (FIG. 6) identifies the outermost structure formed after completion of step 1620.

Method 1600 can continue with step 1625, which includes a second conformal deposition of Aluminum Oxide on the surface resulting from step 1620 (FIGS. 6 and 17). As shown in cross-section in FIG. 7, this second deposition of the second material (e.g., Aluminum Oxide) wraps the structures shown in FIG. 6. A step 1630 of ion milling removes the Aluminum Oxide falling between the structures illustrated in cross-section in FIG. 7, and incidentally causes some erosion of the Aluminum Oxide of the structures (FIG. 8). The structures are then planarized (step 1640) using the carbon as a stop layer, and such that the carbon is then exposed along top surfaces of the structures (cross section of FIG. 9). The carbon is removed (step 1645) with an etch, leaving Aluminum Oxide structures supported by a substrate that had supported the original layer of first material (here, amorphous carbon).

A degree of conformality to be provided by the depositions of second material layers relates to a total thickness of such layers, and generally a variation in thickness should be small relative to a total layer thickness. Other variables that can influence a degree of conformality required include an amount of directional selectivity in the ion milling. A greater selectivity in milling of horizontal surfaces can allow for a less conformal layer, because one functional characteristic required of each layer of second material is that side walls (portions of second material generally perpendicular to a substrate) should remain with structural integrity after removal of the horizontally disposed material, and in the case of the first deposition, exposing the underlying resist. Process conditions also can influence a degree of ion milling selectivity, and for example holding the substrate at a low temperature, e.g., between −20 and −40 degrees Celsius, provides greater selectivity for milling of horizontal surfaces.

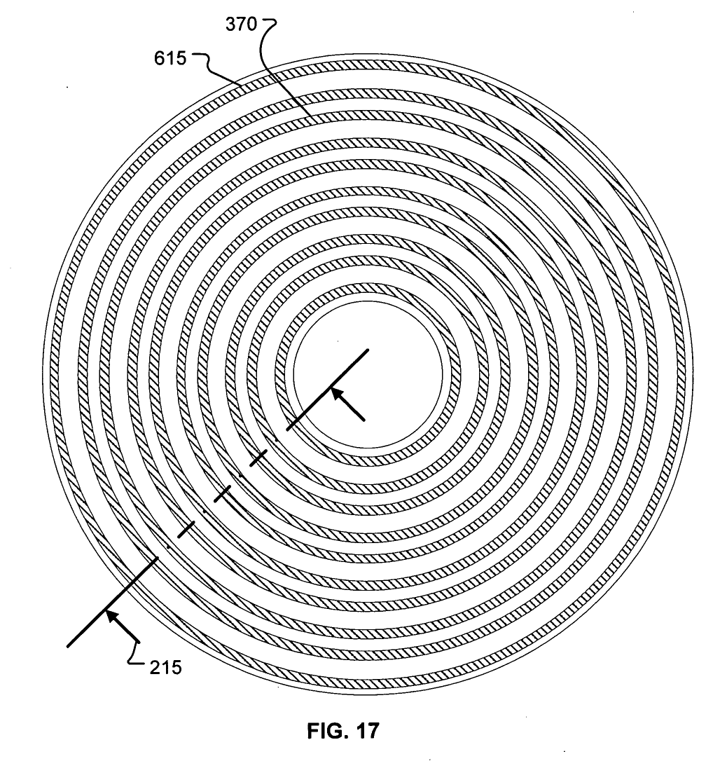

FIG. 18 illustrates a top surface of the second template pattern illustrated in cross-section in FIG. 10, where the original resist pattern was a set of concentric rings. The outermost and inner most formed shapes (here, rings) are identified respectively as 760 and 761 (FIG. 7).

One aspect of the above example was that the resist structure originally deposited had evenly spaced structures generally of the same size. Such a resist structure in these examples results in first (FIG. 6) and second (FIG. 10) template patterns that have unequal spacing between lands and grooves. In some applications, this result may be acceptable or desirable. However, by controlling aspects of the resist pattern, as explained below, other patterns can be obtained, including patterns that have equal spacing (i.e., a groove or a trench) between each land (portion proud from the substrate).

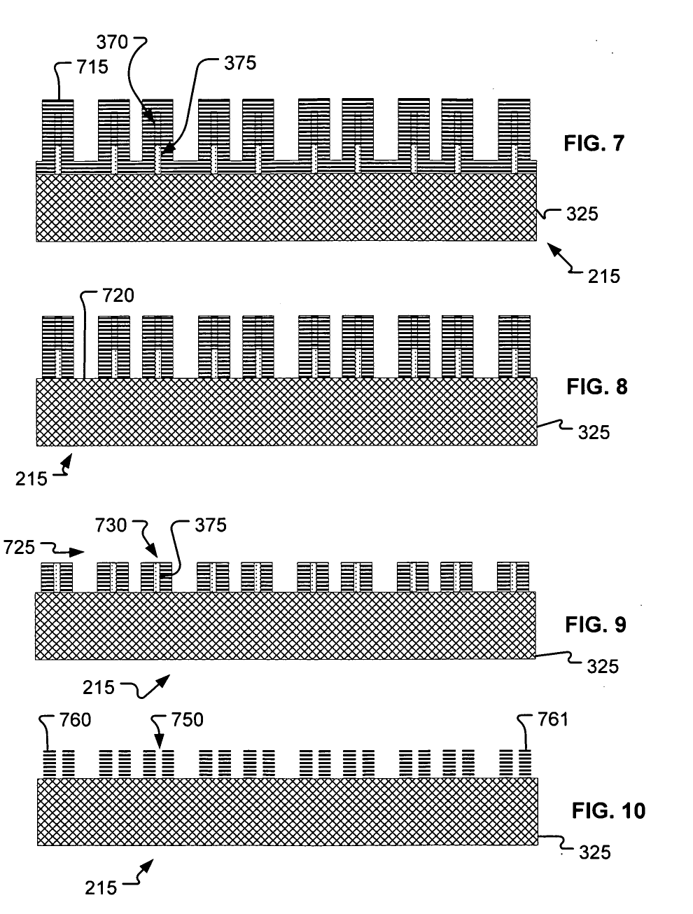

FIGS. 11-15 illustrate a second example build according to the method of FIG. 16, which illustrates such a result. FIG. 11 illustrates a substrate, on which is deposited a layer 1101 of first material, resist structures (one labeled 1102), and a first conformal layer of a second material (1103). A resist pitch 1125, a resist width (Rw) 1110, a spacing (S) 1115 between resist structures, and a thickness (T1) 1120 of the first layer of second material are all indicated. FIG. 12 illustrates the first ion milling, as explained previously. FIG. 13 illustrates both the plasma etch and subsequent deposition of a second layer (1304) of the second material, having a thickness T2 1130. FIG. 14 illustrates the second ion milling step and CMP step, as explained previously. FIG. 15 illustrates the second template pattern, resulting after the last etch step. A final pitch 1135 of the FIG. 15 structures, a gap spacing 1140 between structures, and a width (W) 1145 of the structures are all identified.

The build of FIGS. 11-15 also shows to scale one example ratio of the resist, spacing, and thicknesses of the layers of second material used, resulting in an equal spacing between generally same-sized structures. More formally, one example set of constraints that can be applied are that (1) T2<T1, (2) Rw=T1+2T2, and (3) S=3T1+2T2. The thickness T2 controls the final width 1145 of the second template pattern (FIG. 15) structures, while T1 controls gap spacing 1140 between the structures.

Resist pitch 1125 is equal to Rw+S, and it is evident by comparing FIG. 11 with FIG. 15 that 4 structures fit within the original resist pitch, such that final pitch 1135 is about four times greater than resist pitch 1125.

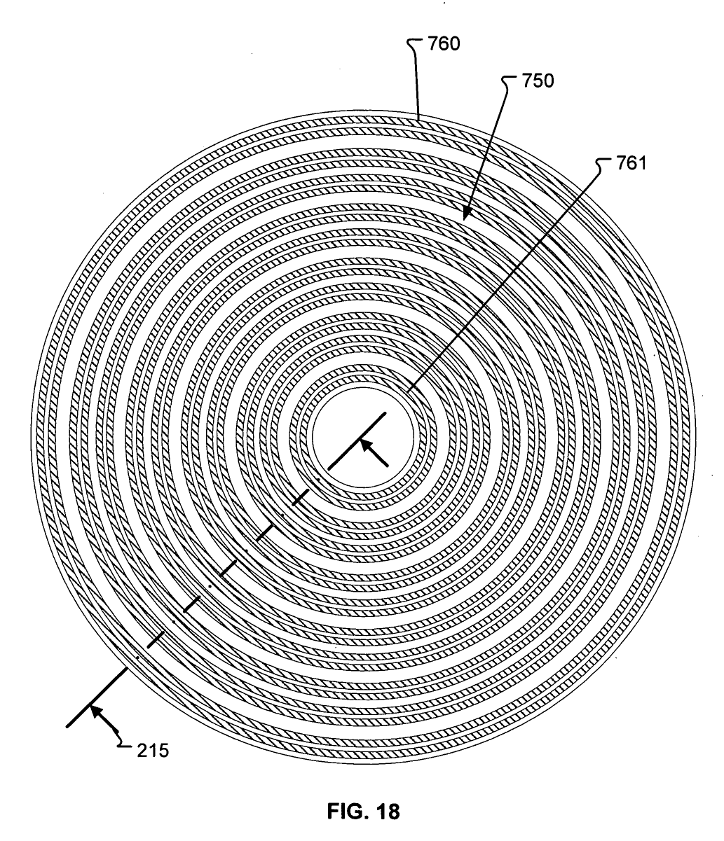

Once a template pattern has been obtained, FIG. 19 depicts an example method 1900 for using the template pattern as a master template in a production-oriented environment. Method 1900 includes obtaining 1905 the master template, and using 1910 the master template to produce one or more production templates. Method 1900 includes using 1915 the production template(s) to emboss patterns in resist, for production of media articles. Of course, the master template and/or production templates can be used for any of a variety of patterning purposes, an example of which is resist embossing.

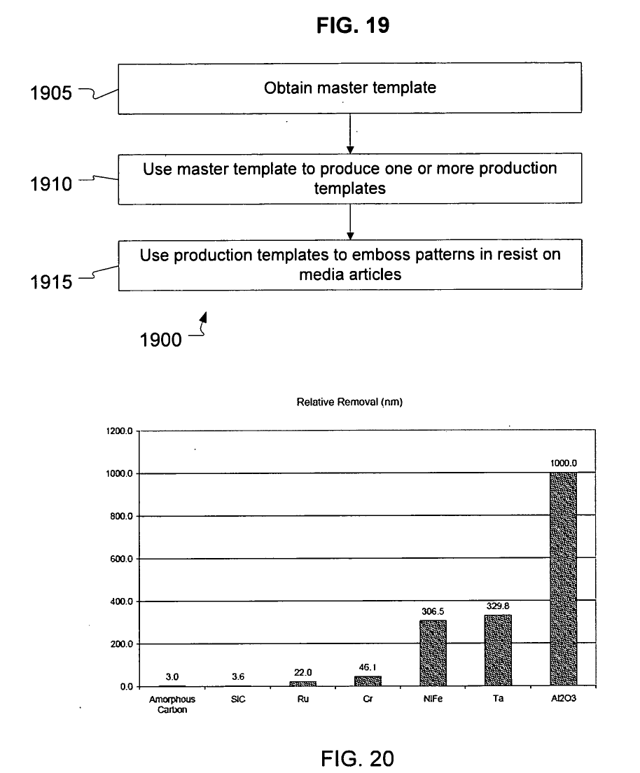

FIG. 20 depicts a chart of relative removal rates of different materials during CMP. As illustrated, there is a large differential between Aluminum Oxide and Amorphous carbon, allowing such carbon to be an effective CMP stop during planarization as described with respect to various figures above. As also illustrated, other materials also exhibit such a differential and may be used in substitution, as long as they allow for the other characteristics required, as explained above. For example, in some cases a material may be unsuitable for different reasons, such as delamination of the layer from the substrate, as was observed in the case of Ta.

In sum, these examples show that a template can be produced that has a pattern with a pitch greater than what can be achieved with a given available direct patterning process (e.g., e-beam direct write). This specification, including the drawings and description thereof present examples and other aspects relating to producing patterns denser than what can be achieved by a given direct-writing strategy. A person of ordinary skill may modify, add to, and otherwise use these examples and disclosures in a vary of contexts and for a variety of activities relating to producing patterns on objects. Thus, the particular application to patterned media, and more particularly to Discrete Track Recording is not by way of limitation, but by way of clarity of example. For example, it would be apparent that a wide variety of shapes can be created according to the disclosed methodology, rather than only concentric rings, as may be preferable in DTR. Further, any given shape, such as a concentric ring may be varied along a radial path, to include, for example, servo patterns. As such, any of these applications remain within the scope of the invention, as defined by the appended claims.

We claim:

1. A processing method for patterned media, comprising:
providing a first layer of a first material, supported by a substrate;
disposing a resist pattern on the first layer, the resist pattern comprising shapes having a respective top surface and one or more side walls;
performing a first deposition of a conformal layer of a second material on the resist pattern;
performing directional ion milling of the second layer to expose the tops of the resist pattern while avoiding exposure of the side walls of the resist pattern; and
removing the resist pattern and portions of the first layer not supporting portions of the second layer to produce a first template pattern formed of the second material supported by the first material.

2. The method of claim 1, wherein the first material is more resistant to ion milling than the second material and less resistant to plasma etching than the second material.

3. The method of claim 1, wherein the substrate has a generally circular planar surface on which is disposed the first layer, the substrate having an axis of rotation proximate the center of the circular planar surface, and the resist pattern shapes comprise a plurality of concentric rings generally centered around the axis of rotation.

4. The method of claim 1, wherein the substrate has a generally circular planar surface on which is disposed the first layer, the substrate having an axis of rotation proximate the center of the circular planar surface, and the resist pattern shapes comprise a plurality of concentric rings generally centered around the axis of rotation, each top surface of each ring having a radial width and a radial separation from previous and subsequent rings, the radial separation being greater than the radial width by about twice a thickness of the first deposition of the conformal layer of the second material.

5. The method of claim 1, further comprising:
performing a second deposition of a conformal layer composed of the second material;
removing the second material from top portions of the structures to expose the remaining first material that was supporting the remaining second material from the first deposition of the second material; and
removing the remaining first material to produce a second template pattern formed of the second material.

6. The method of claim 5, further comprising performing directional ion milling to remove second material that was deposited between structures of the first template pattern during the further deposition.

7. The method of claim 5, wherein the substrate has a generally circular planar surface on which is disposed the first layer, the substrate having an axis of rotation proximate the center of the circular planar surface, and the resist pattern shapes comprise a plurality of concentric rings generally centered around the axis of rotation, each top surface of each ring having a radial width and a radial separation from previous and subsequent rings, the radial separation being greater than the radial width by about twice a thickness of the first deposition of the conformal layer, and a thickness of the second conformal layer deposition of the second material is about one half of the thickness of the first conformal layer deposition of the second material.

8. The method of claim 7, wherein the top surfaces of the concentric resist rings have approximately 20 nm radial widths, and the concentric resist rings are spaced apart at about 40 nm intervals, the thickness of the first conformal layer deposition of the second material is about 10 nm, and the thickness of the second conformal layer deposition of the second material is about 5 nm.

9. The method of claim 5, wherein a thickness (T2) of the second conformal layer deposition of the second material is less than a thickness (T1) of the first deposition of the conformal layer of the second material, the shapes of the resist pattern comprise concentric rings with a radial width (RW) about equal to T1+2T2 and a spacing between the concentric resist rings is about equal to 3T1+2T2.

10. The method of claim 1, wherein the resist pattern further comprises shapes for servo patterns.

11. The method of claim 1, wherein the substrate is shaped generally as a circular plane and has an axis of rotation proximate the center of the circular plane, and the second template pattern comprises a plurality of concentric rings generally centered around the axis of rotation.

12. The method of claim 1, wherein the first template pattern has a feature pitch approximately twice that of a pitch of the rings of the resist pattern, and the second template pattern has a feature pitch approximately four times that of the pitch of the rings of the resist pattern.

13. The method of claim 1, wherein the first material comprises generally amorphous carbon, and the second material comprises aluminum oxide.

14. The method of claim 1, wherein the first material comprises a material selected from the group consisting of generally amorphous carbon, silicon carbide, ruthenium, and chromium.

15. The method of claim 1, wherein the removing of the resist pattern and portions of the first layer of the first material comprises etching with a plasma at a low temperature.

16. The method of claim 15, wherein the plasma is an oxygen containing plasma, and the low temperature is less than about −20 degrees centigrade.

17. The method of claim 1, wherein a thickness of the first conformal layer deposition of the second material is about twice a thickness of the second deposition of the conformal layer of second material.

18. The method of claim 1, wherein the first template pattern is used as a master template to produce production templates.

19. A template for producing patterned media, comprising:
a substrate comprising one or more layers and having a generally planar first surface; and
a plurality of formations proud from the first surface, the formations composed of amorphous carbon supported by the substrate and Al₂O₃ supported by the amorphous carbon.

20. The template of claim 19, wherein the formations comprise concentric rings.

21. The template of claim 20, wherein the concentric rings have an average pitch of less than about 25 nm.

22. The template of claim 20, wherein the concentric rings have an average pitch of about 15 nm.

23. The template of claim 22, wherein the pitch comprises approximately 5 nm from the formations proud from the surface, separated by spacing of about 10 nm.

24. A template produced by a method, comprising:
providing a first layer of a first material, supported by a substrate;
disposing a resist pattern on the first layer, the resist pattern comprising shapes having a respective top surface and one or more side walls;
performing a first deposition of a conformal layer of a second material on the resist pattern, wherein the first material is more resistant to ion milling than the second material and less resistant to plasma etching than the second material;
performing directional ion milling of the second layer to expose the tops of the resist pattern while avoiding exposure of the side walls of the resist pattern; and
removing the resist pattern and portions of the first layer not supporting portions of the second layer, while retaining portions of the first layer supporting portions of the second layer, thereby producing a template having a first template pattern formed of the second material supported by the first material.

25. A template formed by the method according to claim 24 and by steps comprising:
performing a second deposition of a conformal layer composed of the second material;
performing directional ion milling to remove second material that was deposited between structures of the pattern during the further deposition;
removing the second material from top portions of the structures to expose the remaining first material that was supporting the second material from the first deposition of the second material; and
removing the remaining first material to produce a second template pattern formed of the second material supported by the substrate.
